(19) United States
(12) Patent Application Publication
(10) Pub. No.: US 2024/0234097 A1
(43) Pub. Date: Jul. 11, 2024

(54) ETCHING METHOD AND PLASMA PROCESSING APPARATUS

(71) Applicant: Tokyo Electron Limited, Tokyo (JP)

(72) Inventor: Atsushi TAKAHASHI, Kurokawa-gun (JP)

(73) Assignee: Tokyo Electron Limited, Tokyo (JP)

(21) Appl. No.: 18/398,146

(22) Filed: Dec. 28, 2023

(30) Foreign Application Priority Data
Jan. 11, 2023 (JP) 2023-002451

(51) Int. Cl. H01J 37/32; C23C 16/02; C23C 16/04; C23C 16/34; C23C 16/40

(52) U.S. Cl. CPC H01J 37/3244; C23C 16/0236; C23C 16/045; C23C 16/345; C23C 16/401; H01J 2237/334

(57) ABSTRACT

An etching method includes (a) adsorbing a silylating agent having a C—F bond to at least a portion of an etching target film including a silicon-containing film; and (b) etching the etching target film.

### CROSS-REFERENCE TO RELATED APPLICATION

This application is based on and claims the benefit of priority from Japanese Patent Application No. 2023-002451 filed on Jan. 11, 2023, the entire contents of which are incorporated herein by reference.

### FIELD

Exemplary embodiments of the present disclosure relate to an etching method and a plasma processing apparatus.

### BACKGROUND

Japanese Unexamined Patent Publication No. 2018-510515 discloses a method including a step of performing an atomic layer etching process cycle to etch a single-layer of an exposed surface of a substrate, as a method of etching a substrate.

### SUMMARY

In an embodiment, an etching method includes (a) adsorbing a silylating agent having a C—F bond to at least a portion of an etching target film including a silicon-containing film; and (b) etching the etching target film.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a schematic diagram illustrating a plasma processing apparatus according to an exemplary embodiment.

FIG. 2 is a schematic diagram illustrating the plasma processing apparatus according to the exemplary embodiment.

FIG. 3 is a flowchart illustrating an etching method according to the exemplary embodiment.

FIG. 4 is a cross-sectional view of an example substrate to which the method of FIG. 3 may be applied.

FIG. 5 is a cross-sectional view illustrating one step of the etching method according to the exemplary embodiment.

FIG. 6 is a cross-sectional view illustrating one step of the etching method according to the exemplary embodiment.

FIG. 7 is a cross-sectional view of an example substrate to which the method of FIG. 3 may be applied.

FIG. 8 is a cross-sectional view illustrating one step of the etching method according to the exemplary embodiment.

FIG. 9 is a cross-sectional view illustrating one step of the etching method according to the exemplary embodiment.

FIG. 10 is a flowchart illustrating an etching method according to an exemplary embodiment.

FIG. 11 is a cross-sectional view of an example substrate to which the method of FIG. 10 may be applied.

FIG. 12 is a cross-sectional view illustrating one step of the etching method according to the exemplary embodiment.

FIG. 13 is a cross-sectional view illustrating one step of the etching method according to the exemplary embodiment.

FIG. 14A is a cross-sectional view illustrating one step of the etching method according to the exemplary embodiment, and FIG. 14B is a cross-sectional view illustrating one step of the etching method according to the exemplary embodiment.

FIG. 15 is a cross-sectional view illustrating one step of the etching method according to the exemplary embodiment.

FIG. 16 is a cross-sectional view illustrating one step of the etching method according to the exemplary embodiment.

FIG. 17 is a flowchart illustrating an etching method according to an exemplary embodiment.

FIG. 18 is a flowchart illustrating an etching method according to an exemplary embodiment.

FIG. 19 is a cross-sectional view illustrating one step of the etching method according to the exemplary embodiment.

FIG. 20 is a cross-sectional view illustrating one step of the etching method according to the exemplary embodiment.

FIG. 21 is a cross-sectional view illustrating one step of the etching method according to the exemplary embodiment.

FIG. 22 is a diagram illustrating a substrate processing system according to an exemplary embodiment.

### DETAILED DESCRIPTION

Hereinafter, various exemplary embodiments will be described.

In an exemplary embodiment, an etching method includes (a) a step of adsorbing a silylating agent having a C—F bond to at least a portion of an etching target film including a silicon-containing film, and (b) a step of etching the etching target film.

In the etching method, the silylating agent is adsorbed to the silicon-containing film by processing the etching target film with the silylating agent having a C—F bond. Etching is promoted by the presence of a fluorine atom in the vicinity of the film in a location where the silylating agent is adsorbed on the silicon-containing film. Therefore, according to the etching method, the silicon-containing film is efficiently etched.

In (b), the etching target film may be etched by a reaction between the etching target film and a fluorine atom contained in the silylating agent adsorbed to the etching target film.

In (b), the reaction may be promoted by first plasma generated from a first process gas containing at least one selected from the group consisting of an inert gas and an oxygen-containing gas.

In (b), the reaction may be promoted by heating the etching target film.

The silicon-containing film may include at least one selected from the group consisting of a silicon oxide film and a silicon nitride film.

The silicon oxide film is likely to adsorb the silylating agent and is easily etched by the presence of the fluorine atom in the vicinity. Therefore, when the silicon-containing film includes a silicon oxide film, the above effect is more significantly exhibited. In addition, in some cases, the silicon oxide film is formed by oxidation of the surface of a silicon nitride film, and etching is likely to be promoted by adsorbing the silylating agent on the formed silicon oxide film. Therefore, when the silicon-containing film includes a silicon nitride film, the above effect is more significantly exhibited.

The silicon-containing film may include a silicon oxide film and a film other than the silicon oxide film. In the etching method, the silicon oxide film is more likely to adsorb the silylating agent and the etching is more likely to be promoted than in another film (for example, a silicon nitride film or the like). Therefore, in the etching method, when the silicon-containing film includes the silicon oxide film and the film other than the silicon oxide film, it is possible to selectively etch the silicon oxide film.

The silicon-containing film may include a silicon nitride film and a film other than the silicon nitride film and the silicon oxide film. In the etching method, etching of the silicon nitride film is easily promoted as compared with other films (for example, an amorphous carbon film, a tungsten film, a titanium nitride film, or the like) in an environment in which the surface of the silicon nitride film is oxidized. Therefore, in the etching method, when the silicon-containing film includes the silicon nitride film and the film other than the silicon nitride film and the silicon oxide film, it is possible to selectively etch the silicon nitride film.

In an exemplary embodiment, the etching method may include (a) a step of providing a substrate including an etching target film that has at least a recess and includes a silicon-containing film, (b) a step of adsorbing a silylating agent having a C—F bond to at least a portion of a side wall of the recess, and (c) a step of etching the etching target film.

In (b), the silylating agent may be selectively adsorbed in the lower region of the side wall.

In (c), the side wall may be etched by a reaction between the side wall and a fluorine atom contained in the silylating agent adsorbed to the side wall.

In (c), the reaction may be promoted by first plasma generated from a first process gas including at least one selected from the group consisting of an inert gas and an oxygen-containing gas.

In (c), the lower region of the side wall may be etched in the horizontal direction.

The etching method may further include a step of forming a protective film on at least a portion of the side wall after (a) and before (b).

The etching method may further include a step of forming a protective film in the upper region of the side wall after (a) and before (b). At this time, in (c), the lower region of the side wall may be etched in the horizontal direction.

The protective film may be formed by a method selected from the group consisting of an ALD method, a CVD method, and an MLD method.

The protective film has a first thickness on a first region of the side wall of the recess, and has a second thickness smaller than the first thickness on a second region at a position deeper than the first region of the side wall of the recess.

(a) may include (a-1) a step of providing a substrate including the etching target film and a mask on the etching target film, in which the mask has at least one opening, and (a-2) a step of forming the recess by etching the etching target film via the opening with second plasma generated from a second process gas.

The aspect ratio of the recess may be 5 or more.

(b) may include (b-1) a step of adsorbing the silylating agent to at least a portion of the side wall of the recess, and (b-2) a step of removing a portion of the silylating agent adsorbed to the side wall after (b-1).

In an exemplary embodiment, a plasma processing apparatus includes a chamber, a substrate supporter that supports a substrate in the chamber, in which the substrate has the etching target film including a silicon-containing film, and a gas supply configured to supply the silylating agent having a C—F bond into the chamber.

The plasma processing apparatus 1 may further include a controller. The controller may be configured to perform processing of etching the etching target film by a reaction between the etching target film and a fluorine atom contained in the silylating agent adsorbed to the etching target film, after the silylating agent is adsorbed to at least a portion of the etching target film.

Hereinafter, various exemplary embodiments will be described in detail with reference to the drawings. In the drawing, the same or equivalent portions are denoted by the same reference symbols.

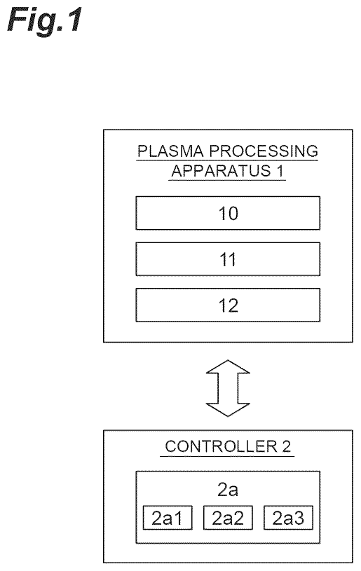

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

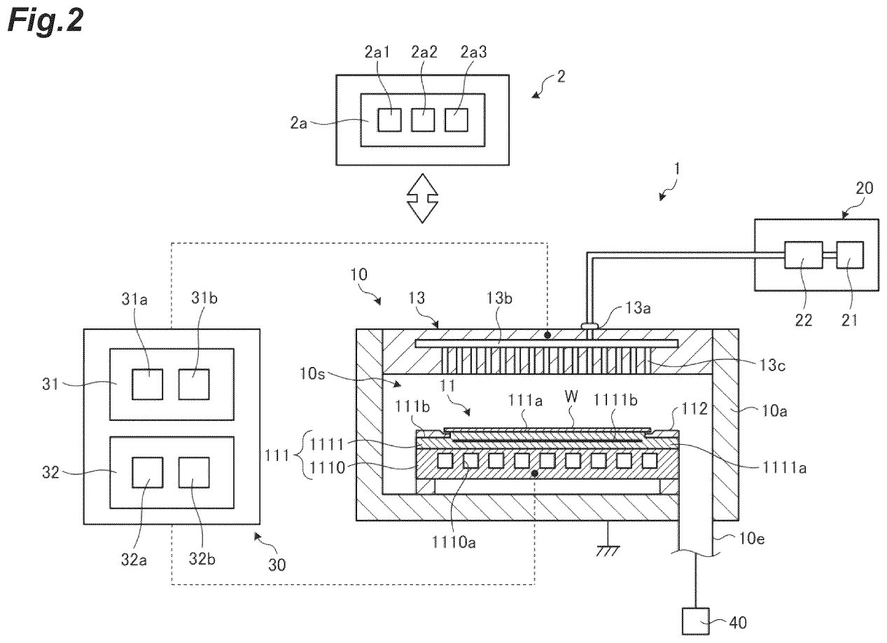

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

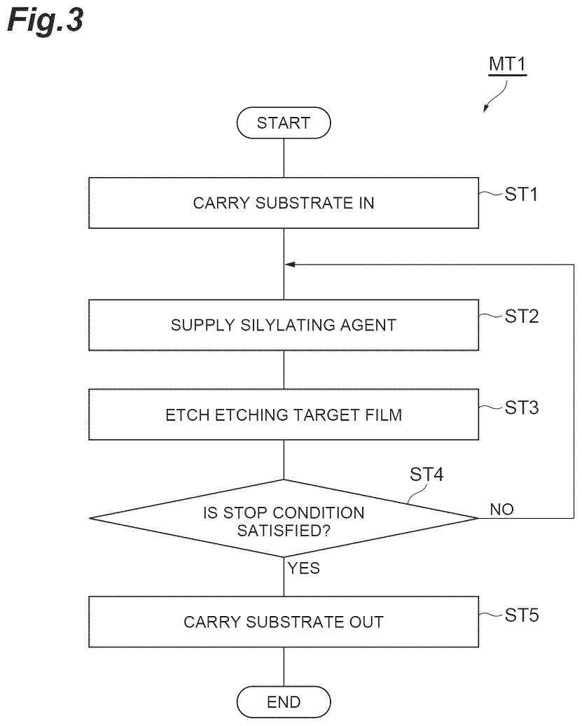

FIG. 3 is a flowchart illustrating an etching method according to the exemplary embodiment. An etching method MT1 (referred to as a “method MT1” below) illustrated in FIG. 3 may be performed by the plasma processing apparatus 1 in the embodiment. The method MT1 may be applied to a substrate W1. That is, a substrate W may be the substrate W1.

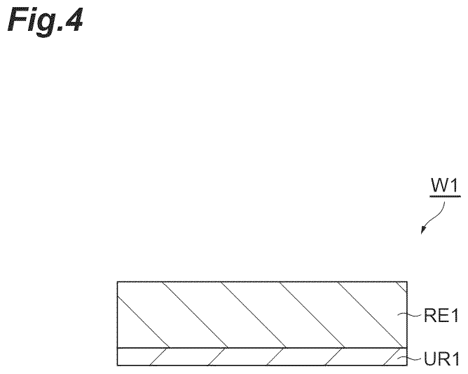

FIG. 4 is a cross-sectional view of a substrate as an example to which the method in FIG. 3 may be applied. As illustrated in FIG. 4, in an embodiment, the substrate W1 has an etching target film RE1. The etching target film RE1 may be provided on an underlying film UR1.

The etching target film RE1 includes a silicon-containing film. The silicon-containing film may include at least one of a silicon film, a silicon germanium film, a silicon oxide film, and a silicon nitride film. The etching target film RE1 may be a silicon-containing film, may be selected from the group consisting of a silicon oxide film and a silicon nitride film, and may be a silicon oxide film.

The underlying film UR1 may contain a material different from the material of the etching target film RE1. The underlying film UR1 may include at least one of a silicon-containing film, an organic film, and a metal-containing film.

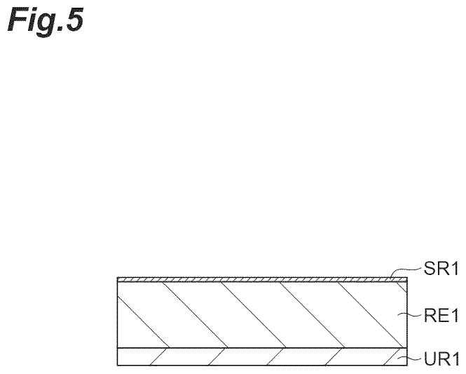

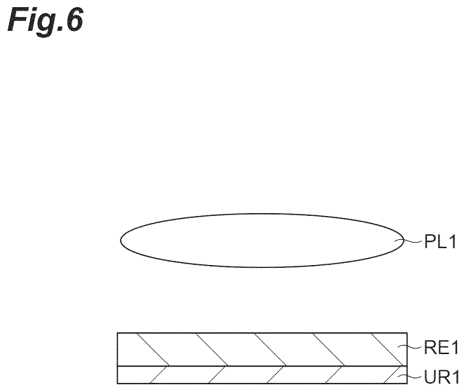

The method MT1 will be described with reference to FIGS. 3 to 6 by using, as an example, the case where the method MT1 is applied to the substrate W1 by using the plasma processing apparatus 1 in the above embodiment. Each of FIGS. 5 and 6 is a cross-sectional view illustrating one step of the etching method according to the exemplary embodiment. When the plasma processing apparatus 1 is used, the method MT1 may be performed in the plasma processing apparatus 1 in a manner that the controller 2 controls each unit of the plasma processing apparatus 1. In the method MT1, the substrate W (for example, the substrate W1) on a substrate support 11 (substrate supporter) disposed in a plasma processing chamber 10 as illustrated in FIG. 2 may be processed.

As illustrated in FIG. 3, the method MT1 may include Steps ST1 to ST5. Steps ST1 to ST5 may be performed in order. The method MT1 does not need to include at least one of Steps ST4 and ST5.

In Step ST1, a substrate W1 illustrated in FIG. 4 is provided. The substrate W1 may be carried into the plasma processing chamber 10. The substrate W1 may be supported by the substrate support 11 in the plasma processing chamber 10.

In Step ST2, as illustrated in FIG. 5, a silylating agent is supplied on the etching target film RE1 of the substrate W1 and the silylating agent is adsorbed to at least a portion of the surface of the etching target film RE1. In Step ST2, an adsorption site SR1 to which the silylating agent has been adsorbed may be formed on at least a portion of the surface of the etching target film RE1. In FIG. 5, the adsorption site SR1 is illustrated in a layered form. In Step ST2, a layer does not need to be formed by the adsorption of the silylating agent. That is, the adsorption site SR1 in FIG. 5 only schematically indicates a site where the silylating agent is adsorbed on the surface of the etching target film RE1, and it is not necessary to form a layer corresponding to the adsorption site SR1 on the etching target film RE1.

Step ST2 may be performed by supplying a process gas containing the silylating agent into the plasma processing chamber 10 by the gas supply 20. The controller 2 controls the gas supply 20 such that the silylating agent is adsorbed to at least a portion of the surface of the etching target film RE1.

The silylating agent may be a silylating agent having a fluorine-containing group having a C—F bond. Examples of the fluorine-containing group include an alkyl fluoride group, an aryl fluoride group, and the like.

The alkyl fluoride group can also refer to a group in which some or all of hydrogen atoms of an alkyl group are substituted with fluorine atoms. The carbon number of the alkyl group (alkyl fluoride group) may be, for example, 1 or more, and may be 2 or more, 4 or more, or 6 or more. The carbon number of the alkyl group (alkyl fluoride group) may be, for example, 20 or less, 16 or less, or 14 or less.

The aryl fluoride group can also refer to a group in which some or all of hydrogen atoms of an aryl group are substituted with fluorine atoms. The carbon number of the aryl group (the aryl fluoride group) may be, for example, 6 to 18, 6 to 12, or 6 to 10. The aryl group may be, for example, a phenyl group. That is, the aryl fluoride group may be, for example, a phenyl fluoride group.

The silylating agent may further have a reactive group capable of forming a linking group that links a silicon atom in the silicon-containing film and an atom in the silylating agent by reacting with a hydroxyl group present on the surface of the silicon-containing film. The linking group may be, for example, a group represented by —O—.

The reactive group may be a group that is bonded to a silicon atom in the silylating agent. In this case, a linking group that links the silicon atom in the silicon-containing film and the silicon atom in the silylating agent is formed. The reactive group may be, for example, a hydroxyl group (—OH), an alkoxy group (—OR¹), an aryloxy group (—OR²), an amino group (—NR³R⁴), a halogeno group (—X), or the like.

R¹ represents an alkyl group, and the carbon number of the alkyl group may be, for example, 1 to 20, 1 to 16, 1 to 12, 1 to 8, or 1 to 4. R² represents an aryl group, and the carbon number of the aryl group may be, for example, 6 to 18, 6 to 12, or 6 to 10. The aryl group may be, for example, a phenyl group.

R³ and R⁴ may each independently be a hydrogen atom, an alkyl group, or an aryl group. The carbon number of the alkyl group may be, for example, 1 to 20, 1 to 16, 1 to 12, 1 to 8, or 1 to 4. The carbon number of the aryl group may be, for example, 6 to 18, 6 to 12, or 6 to 10. The aryl group may be, for example, a phenyl group.

X represents a halogen atom. X may be, for example, a chlorine atom, a bromine atom, or an iodine atom. X may be, for example, a chlorine atom.

A boiling point of the silylating agent may be, for example, 400° C. or lower, 350° C. or lower, or 300° C. or lower. The boiling point of the silylating agent may be, for example, 50° C. or higher, or 100° C. or higher, or 200° C. or higher.

Examples of the silylating agent include trialkoxy (1H,1H,2H,2H-heptadecafluorodecyl)silane (for example, trimethoxy (1H,1H,2H,2H-heptadecafluorodecyl)silane, triethoxy(1H,1H,2H,2H-heptadecafluorodecyl)silane, and the like), trichloro(1H,1H,2H,2H,-heptadecafluorodecyl)silane, chlorodimethyl (1H,1H,2H,2H-heptadecafluorodecyl)silane, and the like.

In Step ST3, as illustrated in FIG. 6, the etching target film RE1 is etched by first plasma PL1 generated from the first process gas. In Step ST3, the etching target film RE1 may be etched by promoting a reaction between the etching target film RE1 and the fluorine atom contained in the silylating agent adsorbed to the surface of the etching target film RE1 with the first plasma PL1 generated from the first process gas.

The first process gas may contain an inert gas. The inert gas may include at least one of a nitrogen gas and a noble gas. The noble gas may be an argon (Ar) gas, a krypton (Kr) gas, a xenon (Xe) gas, or the like. The first process gas may contain an oxygen-containing gas instead of the inert gas or in addition to the inert gas. The oxygen-containing gas may be, for example, an oxygen (O₂) gas, a carbon monoxide (CO) gas, or a carbon dioxide (CO₂) gas.

Step ST3 may be performed as follows. First, the gas supply 20 supplies the first process gas into the plasma processing chamber 10. Then, a plasma generator 12 generates the first plasma PL1 from the first process gas in the plasma processing chamber 10. The controller 2 controls the gas supply 20 and the plasma generator 12 such that the etching target film RE1 is etched with the first plasma PL1. The controller 2 may control the gas supply 20 and the plasma generator 12 such that the etching target film RE1 is etched by promoting a reaction between the etching target film RE1 and the fluorine atom contained in the silylating agent adsorbed to the surface of the etching target film RE1 with the first plasma PL1.

In Step ST3, the reaction between the etching target film RE1 and the fluorine atoms may be promoted by heating the substrate W1 using a heating device instead of the first plasma PL1 or in addition to the first plasma PL1. The heating device may be, for example, one or a plurality of heaters disposed in a ceramic member 1111a of an electrostatic chuck 1111. In addition, the heating device may be, for example, an infrared lamp or the like. The heating temperature may be, for example, 100° C. or higher and 400° C. or lower.

In the method MT1, Step ST2 and Step ST3 may be repeated. At this time, the method MT1 may include Step ST4. In Step ST4, whether or not a stop condition is satisfied is determined. In Step ST4, the stop condition may be satisfied, for example, when the number of times of the repetition reaches a predetermined number of times. Further, in Step ST4, the stop condition may be satisfied, for example, when the thickness of the etching target film RE1 reaches a predetermined thickness.

In Step ST4, when it is determined that the stop condition is not satisfied, Steps ST2 and ST3 are performed again. In Step ST4, when it is determined that the stop condition is satisfied, Step ST5 is performed, or the method MT1 is ended.

In Step ST5, the etched substrate W1 is carried out from the plasma processing chamber 10.

According to the method MT1 described above, since the silylating agent is adsorbed to the etching target film RE1 in Step ST2, the etching efficiency in Step ST3 is excellent.

The method MT1 described above may also be applied to a substrate W2. That is, the substrate W may also be the substrate W2. A case where the method MT1 is applied to the substrate W2 (a “method MT1′” below) will be described below.

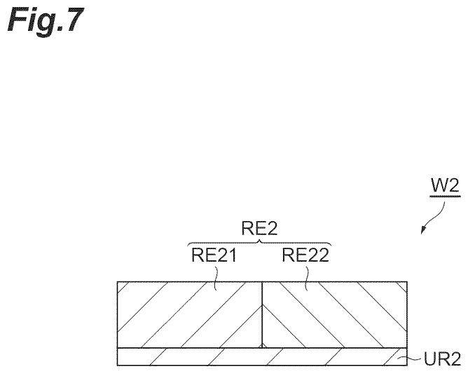

FIG. 7 is a cross-sectional view of an example substrate to which the method MT1′ may be applied. As illustrated in FIG. 7, in an embodiment, the substrate W2 has an etching target film RE2. The etching target film RE2 may be provided on an underlying film UR2. The etching target film RE2 may have a silicon oxide film RE21 and a film RE22 (referred to as “another film RE22” below) other than the silicon oxide film. The other film RE22 may be a silicon-containing film such as a silicon film, a silicon germanium film, or a silicon nitride film, or may be an organic film such as an amorphous carbon film.

The underlying film UR2 may contain a material different from the material of the etching target film RE2. The underlying film UR2 may include at least one of a silicon-containing film, an organic film, and a metal-containing film.

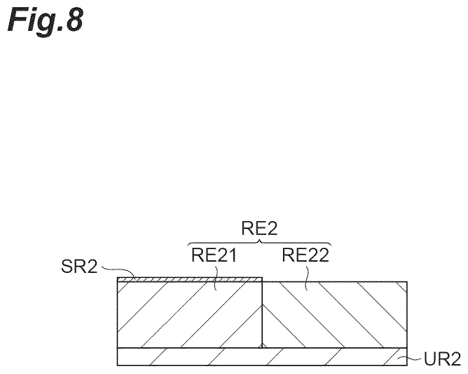

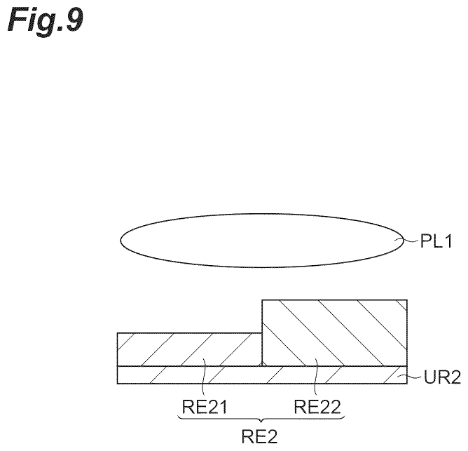

The method MT1′ will be described with reference to FIGS. 3, 7 to 9 by using, as an example, the case where the method MT1′ is applied to the substrate W2 by using the plasma processing apparatus 1 in the above embodiment. Each of FIGS. 8 and 9 is a cross-sectional view illustrating one step of the etching method according to the exemplary embodiment. When the plasma processing apparatus 1 is used, the method MT1′ may be performed in the plasma processing apparatus 1 in a manner that the controller 2 controls each unit of the plasma processing apparatus 1. In the method MT1′, the substrate W (for example, the substrate W2) on the substrate support 11 (substrate supporter) disposed in the plasma processing chamber 10 as illustrated in FIG. 2 may be processed.

As illustrated in FIG. 3, the method MT1′ may include Steps ST1 to ST5. Steps ST1 to ST5 may be performed in order. The method MT1′ does not need to include at least one of Steps ST4 and ST5.

In Step ST1, a substrate W2 illustrated in FIG. 7 is provided. The substrate W2 may be carried into the plasma processing chamber 10. The substrate W2 may be supported by the substrate support 11 in the plasma processing chamber 10.

In Step ST2, as illustrated in FIG. 8, the silylating agent is supplied on the etching target film RE2 of the substrate W2 and the silylating agent is adsorbed to at least a portion of the surface of the etching target film RE2. In Step ST2, an adsorption site SR2 to which the silylating agent has been adsorbed may be formed on at least a portion of the surface of the etching target film RE2. In FIG. 8, the adsorption site SR2 is illustrated in a layered form. In Step ST2, a layer does not need to be formed by the adsorption of the silylating agent. That is, the adsorption site SR2 in FIG. 8 only schematically indicates a site where the silylating agent is adsorbed on the surface of the etching target film RE2, and it is not necessary to form a layer corresponding to the adsorption site SR2 on the etching target film RE2.

In Step ST2, as illustrated in FIG. 8, the silylating agent may be selectively adsorbed to the silicon oxide film RE21 in the etching target film RE2 of the substrate W2. In Step ST2, the silylating agent may or may not be adsorbed on the other film RE22. The silylating agent may be as described above.

In Step ST3, as illustrated in FIG. 9, the silicon oxide film RE21 provided in the etching target film RE2 is etched by first plasma PL1 generated from the first process gas. In Step ST3, the silicon oxide film RE21 may be etched by promoting a reaction between the silicon oxide film RE21 and the fluorine atom contained in the silylating agent adsorbed to the surface of the silicon oxide film RE21 with the first plasma PL1 generated from the first process gas.

The first process gas may contain an inert gas. The inert gas may include at least one of a nitrogen gas and a noble gas. The noble gas may be an argon (Ar) gas, a krypton (Kr) gas, a xenon (Xe) gas, or the like. The first process gas may contain an oxygen-containing gas instead of the inert gas or in addition to the inert gas. The oxygen-containing gas may be, for example, an oxygen (O₂) gas, a carbon monoxide (CO) gas, or a carbon dioxide (CO₂) gas.

In Step ST3, the etching rate of the silicon oxide film RE21 may be higher than the etching rate of the other film RE22. That is, in Step ST3, the silicon oxide film RE21 may be selectively etched. In Step ST3, the other film RE22 may or may not be etched.

In Step ST3, the silicon oxide film RE21 may be completely removed by etching or may remain with a predetermined film thickness.

Step ST3 may be performed as follows. First, the gas supply 20 supplies the first process gas into the plasma processing chamber 10. Then, a plasma generator 12 generates the first plasma PL1 from the first process gas in the plasma processing chamber 10. The controller 2 controls the gas supply 20 and the plasma generator 12 such that the silicon oxide film RE21 provided in the etching target film RE2 is etched with the first plasma PL1. The controller 2 may control the gas supply 20 and the plasma generator 12 such that the silicon oxide film RE21 is etched by promoting a reaction between the silicon oxide film RE21 and the fluorine atom contained in the silylating agent adsorbed to the surface of the silicon oxide film RE21 with the first plasma PL1.

In Step ST3, the reaction between the silicon oxide film RE21 and the fluorine atoms may be promoted by heating the substrate W1 using a heating device instead of the first plasma PL1 or in addition to the first plasma PL1. The heating device may be, for example, one or a plurality of heaters disposed in a ceramic member 1111a of an electrostatic chuck 1111. In addition, the heating device may be, for example, an infrared lamp or the like. The heating temperature may be, for example, 100° C. or higher and 400° C. or lower.

In the method MT1′, Step ST2 and Step ST3 may be repeated. At this time, the method MT1′ may include Step ST4. In Step ST4, whether or not a stop condition is satisfied is determined. In Step ST4, the stop condition may be satisfied, for example, when the number of times of the repetition reaches a predetermined number of times. Further, in Step ST4, the stop condition may be satisfied, for example, when the thickness of the etching target film RE1 (for example, the thickness of the silicon oxide film RE21 or the thickness of the other film RE22) has reached a predetermined thickness.

In Step ST4, when it is determined that the stop condition is not satisfied, Steps ST2 and ST3 are performed again. In Step ST4, when it is determined that the stop condition is satisfied, Step ST5 is performed, or the method MT1 is ended.

In Step ST5, the etched substrate W2 is carried out from the plasma processing chamber 10.

According to the method MT1′ described above, the silicon oxide film RE21 is likely to adsorb the silylating agent and is easily affected by the adsorption of the silylating agent. Therefore, it is possible to etch the silicon oxide film RE21 in Step ST3 at a higher etching rate than the etching rate of the other film RE22.

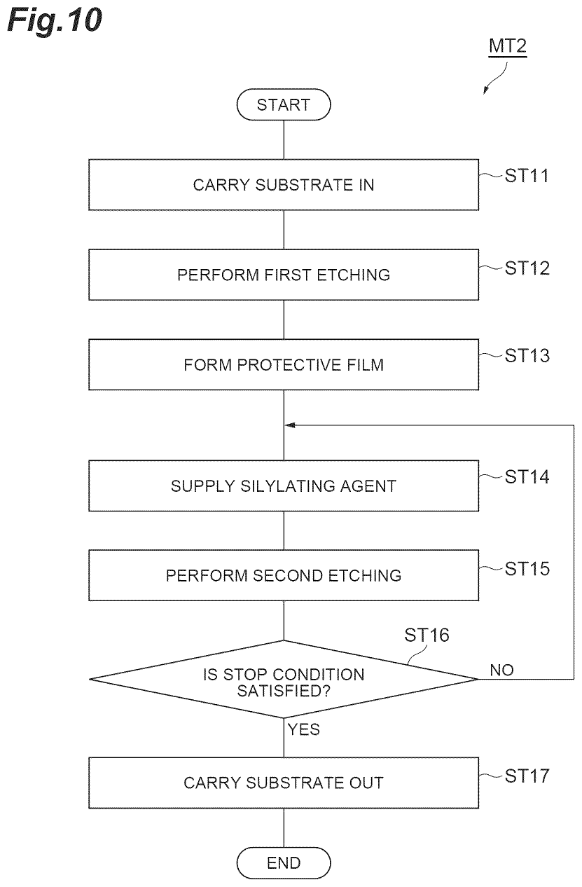

FIG. 10 is a flowchart illustrating an etching method according to an exemplary embodiment. An etching method MT2 (referred to as a “method MT2” below) illustrated in FIG. 10 may be performed by the plasma processing apparatus 1 in the embodiment. The method MT2 may be applied to a substrate W3. That is, the substrate W may be the substrate W3.

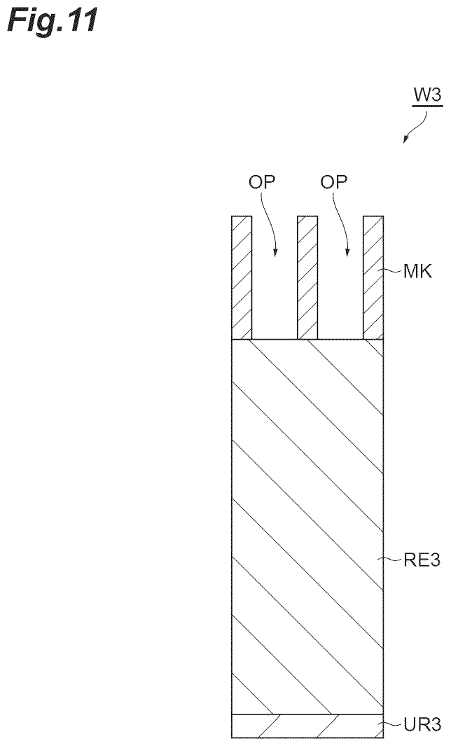

FIG. 11 is a cross-sectional view of an example substrate to which the method of FIG. 10 may be applied. As illustrated in FIG. 11, in the embodiment, the substrate W3 has an etching target film RE3 and a mask MK on the etching target film RE3. The etching target film RE3 may be provided on an underlying film UR3. The mask MK may have at least one opening OP.

The etching target film RE3 includes a silicon-containing film. The silicon-containing film may include at least one of a silicon film, a silicon germanium film, a silicon oxide film, and a silicon nitride film. The etching target film RE3 may be a silicon-containing film or a silicon oxide film.

The mask MK may contain at least one of a silicon-containing substance, an organic matter, and a metal. The silicon-containing substance may include polysilicon. The organic matter may contain at least one of a photoresist and a Spin On Carbon (SOC). The mask MK may contain at least one of a second silicon-containing substance, an organic matter, and a metal configuring the silicon-containing film in the etching target film RE3. The second silicon-containing substance is different from the first silicon-containing substance.

The underlying film UR3 may contain a material different from the material of the etching target film RE3. The underlying film UR3 may include at least one of a silicon-containing film, an organic film, and a metal-containing film.

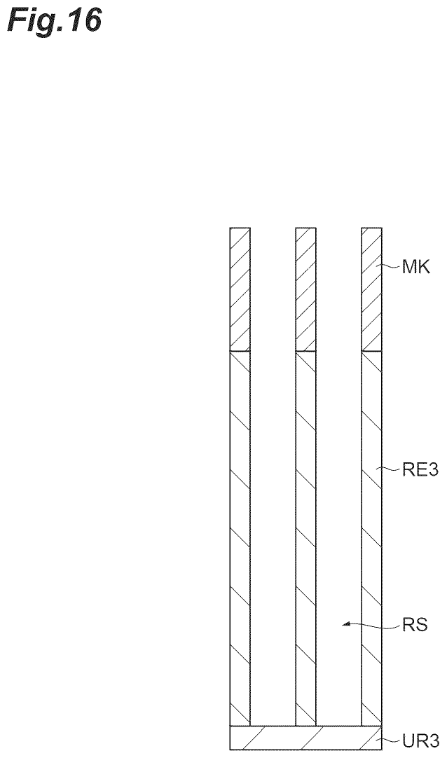

The method MT2 will be described with reference to FIGS. 10 to 16 by using, as an example, the case where the method MT2 is applied to the substrate W3 by using the plasma processing apparatus 1 in the above embodiment. Each of FIGS. 11 and 16 is a cross-sectional view illustrating one step of the etching method according to the exemplary embodiment. When the plasma processing apparatus 1 is used, the method MT2 may be performed in the plasma processing apparatus 1 in a manner that the controller 2 controls each unit of the plasma processing apparatus 1. In the method MT2, the substrate W (for example, the substrate W3) on the substrate support 11 (substrate supporter) disposed in the plasma processing chamber 10 as illustrated in FIG. 2 may be processed.

As illustrated in FIG. 10, the method MT2 may include Steps ST11 to ST17. Steps ST11 to ST17 may be performed in order. The method MT2 does not need to include at least one of Steps ST11 to ST13 and ST16 and ST17.

In Step ST11, the substrate W3 illustrated in FIG. 11 is provided. The substrate W3 may be carried into the plasma processing chamber 10. The substrate W3 may be supported by the substrate support 11 in the plasma processing chamber 10.

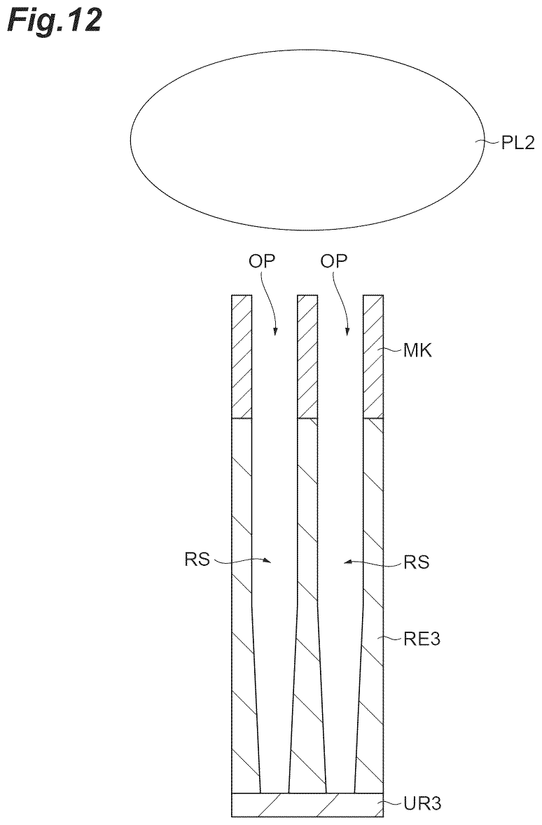

In Step ST12, as illustrated in FIG. 12, the etching target film RE3 is etched by second plasma PL2 generated from a second process gas, and thereby forming a recess RS. The recess RS may correspond to the opening OP of the mask MK. The dimension of the recess RS at the upper end of the recess RS may be 100 nm or less. The dimension of the recess RS may be gradually reduced from the upper end to the bottom of the recess RS. That is, the recess RS may have a tapered shape. The bottom of the recess RS may or may not reach the underlying film UR3.

The aspect ratio of the recess RS may be, for example, 5 or more, and may be 10 or more, 20 or more, 30 or more, 40 or more, or 50 or more. The aspect ratio of the recess RS may be, for example, 200 or less. The aspect ratio of the recess RS indicates the ratio of the depth of the recess RS with respect to the maximum width dimension of the recess RS.

The second process gas may contain a halogen-containing gas. The halogen-containing gas may include at least one of a fluorine-containing gas and a chlorine-containing gas. When the etching target film RE3 includes a silicon oxide film or a silicon nitride film, the second process gas may contain a fluorine-containing gas. When the etching target film RE3 includes a silicon film or a silicon germanium film, the second process gas may contain a chlorine-containing gas. Examples of the fluorine-containing gas include a fluorocarbon (CₓF_{y}) gas, a hydrofluorocarbon (CₓH_{y}F_{z}) gas, and a nitrogen trifluoride (NF₃) gas. x, y and z are natural numbers. The second process gas may further contain an oxygen-containing gas.

Step ST12 may be performed as follows. First, the gas supply 20 supplies the second process gas into the plasma processing chamber 10. Then, the plasma generator 12 generates the second plasma PL2 from the second process gas in the plasma processing chamber 10. The controller 2 controls the gas supply 20 and the plasma generator 12 such that the etching target film RE3 is etched with the second plasma PL2 to form the recess RS.

In Step ST12, a reaction product generated by etching may be attached to the side wall of the recess RS. Therefore, a step (ashing step) of removing the reaction product may be performed before Step ST13. The reaction product is removed by oxygen plasma generated from an oxygen gas, for example.

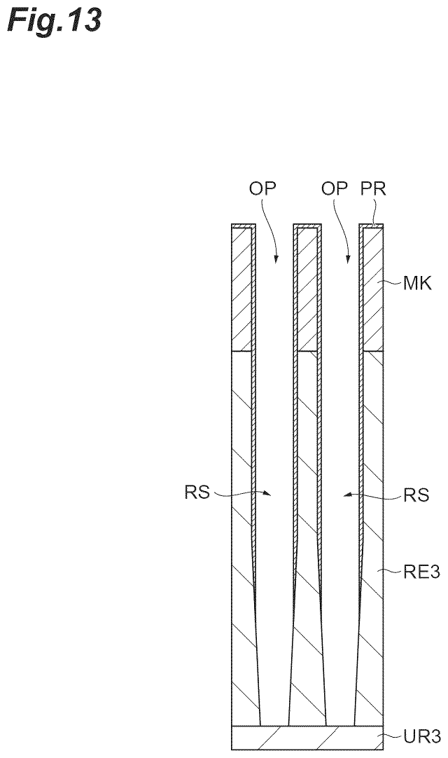

In Step ST13, as illustrated in FIG. 13, a protective film PR is formed on at least a portion of the side wall of the recess RS. The protective film PR may be selectively formed in the shallow region or a region from the shallow region of the recess RS to the intermediate region (upper region). The protective film PR may also be formed on the side wall of the opening OP. The protective film PR may also be formed on the upper surface of the mask MK. It is not necessary to perform Step ST13. For example, when the silylating agent can be selectively adsorbed to a deep region (lower region) of the recess RS in Step ST14, Step ST13 does not need to be performed. The lower region of the recess RS may be a region having a depth of 50 to 100, a region having a depth of 60 to 100, or a region having a depth of 70 to 100 when the depth to the bottom surface of the recess RS is set as 100. The upper region of the recess RS may indicate a region shallower than the lower region. For example, the upper region of the recess RS may be a region having a depth 0 to 50, a region having a depth 0 to 60, or region having a depth 0 to 70 when the depth to the bottom surface of the recess RS is set as 100.

The protective film PR may have a first thickness in a first region on the opening OP side of the side wall of the recess RS, and may have a second thickness in a second region on the bottom surface side of the side wall of the recess RS. The second thickness is smaller than the first thickness. The thickness of the protective film PR may be gradually reduced from the upper surface of the mask MK toward the bottom of the recess RS. The protective film PR is a non-conformal film (a sub-conformal film). The protective film PR does not need to be formed at the bottom of the recess RS. At least a portion of the side wall and the bottom surface of the recess RS of the etching target film RE3 may not be covered with the protective film PR and be exposed.

The protective film PR may include at least one of a silicon-containing film, an organic film, and a metal-containing film. The silicon-containing film may include at least one of a silicon oxide film and a silicon nitride film.

The protective film PR may be formed by using a process gas for forming a protective film. The process gas for forming the protective film may contain at least one of a silicon-containing gas, a carbon-containing gas, and a metal-containing gas.

The protective film PR may be formed by an atomic layer deposition (ALD) method, a chemical vapor deposition (CVD) method, or a multi-layer deposition (MLD) method. Examples of the ALD method include a thermal ALD method and a plasma enhanced (PE)-ALD method. When the protective film PR is formed by the PE-ALD method, Steps ST13 include an adsorption step of supplying a precursor (process gas for forming the protective film) to the side wall of the recess RS, and an activation step of activating the adsorbed precursor. The activation may be performed by plasma generated from a process gas. The adsorption step and the activation step may be alternately repeated. A purge step may be performed between the adsorption step and the activation step. The thickness of the protective film PR may be adjusted by controlling the precursor not to be adsorbed to a portion of the surface of the substrate W3 (for example, the bottom of the recess) in the adsorption step. For example, an adsorption position can be controlled by forming a factor that inhibits the adsorption of the precursor on a portion of the surface of the substrate W3. Alternatively, in the activation step, the thickness of the protective film PR may be adjusted by performing control such that the plasma does not reach a portion of the surface of the substrate W3 (for example, the bottom of the recess).

When the protective film PR includes a silicon-containing film, a silicon-containing gas is used as the precursor in the adsorption step. When the protective film PR includes a silicon oxide film, examples of the silicon-containing gas include an aminosilane gas, a SiCl₄ gas, and a SiF₄ gas. In the activation step, an oxygen-containing gas is used as the process gas. Examples of the oxygen-containing gas include an oxygen gas. When the protective film PR includes a silicon nitride film, examples of the silicon-containing gas include an aminosilane gas, a SiCl₄ gas, a dichlorosilane gas, and a hexachlorodisilane gas. In the activation step, a nitrogen-containing gas is used as the process gas. Examples of the nitrogen-containing gas include a nitrogen gas and an ammonia gas.

When the protective film PR includes an organic film, an organic gas is used as the precursor in the adsorption step. Examples of the organic gas include epoxides, carboxylic acids, carboxylic acid halides, anhydride carboxylic acids, isocyanates, and phenols. In the activation step, various gases are used as the process gas. Examples of various gases include an inorganic compound gas having an N—H bond, an inert gas, a water vapor (H₂O gas), a gas mixture of a nitrogen gas and a hydrogen gas, and a gas mixture of a hydrogen gas and an oxygen gas. When the protective film PR includes a metal film, a metal-containing gas is used as the precursor in the adsorption step. The metal-containing gas may contain at least one of an oxygen-containing metal compound, a nitrogen-containing metal compound, a sulfur-containing metal compound, and a metal halide. Examples of the metal halide include TiCl₄, WF₆, WCl₅, WCl₆, SnCl₄, SnBr₄, and SnI₄. In the activation step, at least one of a hydrogen-containing gas and an oxygen-containing gas is used as the process gas. In a case of using a hydrogen-containing gas, the protective film PR is a metal-containing film. In a case of using an oxygen-containing gas, the protective film PR is a metal oxide film. The hydrogen-containing gas may contain nitrogen. In this case, the protective film PR is a metal nitride film. Examples of the hydrogen-containing gas containing nitrogen include an ammonia gas and a gas mixture of a nitrogen gas and a hydrogen gas.

Step ST13 may be performed as follows. First, the gas supply 20 supplies the process gas for forming the protective film into the plasma processing chamber 10. Then, the plasma generator 12 generates the plasma from the process gas in the plasma processing chamber 10. The controller 2 controls the gas supply 20 and the plasma generator 12 such that the protective film PR is formed on the side wall of the recess RS by plasma.

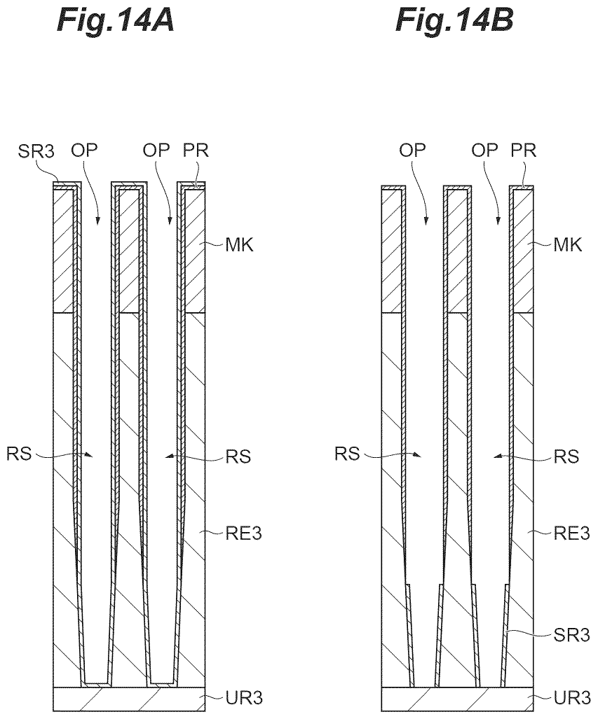

In Step ST14, as illustrated in FIGS. 14A and 14B, the silylating agent is supplied on the etching target film RE3 of the substrate W3 and the silylating agent is adsorbed to at least a portion of the surface of the etching target film RE3. In Step ST14, an adsorption site SR3 to which the silylating agent has been adsorbed may be formed on at least a portion of the surface of the etching target film RE3. In FIGS. 14A and 14B, the adsorption site SR3 is illustrated in a layered form. In Step ST14, a layer does not need to be formed by the adsorption of the silylating agent. That is, the adsorption site SR3 in FIGS. 14A and 14B only schematically indicates the site where the silylating agent is adsorbed, and it is not necessary to form a layer corresponding to the adsorption site SR3 on the substrate W3. The silylating agent may be as described above.

In Step ST14, as illustrated in FIG. 14A, the silylating agent may be adsorbed on the protective film PR. The silylating agent may be adsorbed to the side wall of the recess RS, may be adsorbed to the bottom surface of the recess RS, may be adsorbed to the underlying film UR3, may be adsorbed to the side wall of the opening OP, and may be adsorbed to the upper surface of the mask MK. In Step ST14, as illustrated in FIG. 14B, the silylating agent does not need to be adsorbed to the protective film PR and the underlying film UR3.

Further, in Step ST14, the silylating agent may be supplied onto the etching target film RE3 of the substrate W3, and the silylating agent may be adsorbed to the surface of the etching target film RE3. Then, the silylating agent on the etching target film RE3 in the shallow region of the recess RS may be removed by a predetermined method, and the silylating agent may be selectively adsorbed to the deep region (lower region) of the recess RS. As a result, it is possible to selectively promote etching in the deep region (lower region) of the recess RS. The method of removing the silylating agent in the shallow region is not particularly limited, and removal, for example, with an oxygen radical may be performed. When Step ST14 is a step capable of selectively adsorbing the silylating agent to the deep region (lower region) of the recess RS as described above, Step ST14 may be performed after Step ST12 without performing Step ST13.

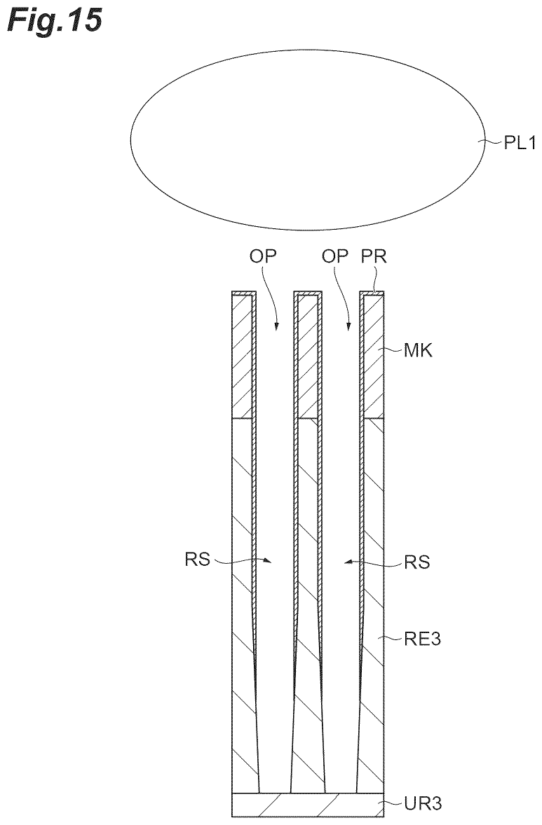

In Step ST15, as illustrated in FIG. 15, the etching target film RE3 is etched by first plasma PL1 generated from the first process gas. In Step ST15, the protective film PR may also be etched.

When the bottom of the recess RS reaches the underlying film UR in Step ST12, the side wall of the recess RS is mainly etched in Step ST15. In Step ST15, for example, the lower region of the side wall of the recess RS may be etched in the horizontal direction. When the bottom of the recess RS does not reach the underlying film UR in Step ST12, the bottom of the recess RS is mainly etched in Step ST15.

The first process gas may contain an inert gas. The inert gas may include at least one of a nitrogen gas and a noble gas. The noble gas may be an argon (Ar) gas, a krypton (Kr) gas, a xenon (Xe) gas, or the like. The first process gas may contain an oxygen-containing gas instead of the inert gas or in addition to the inert gas. The oxygen-containing gas may be, for example, an oxygen (O₂) gas, a carbon monoxide (CO) gas, or a carbon dioxide (CO₂) gas.

Step ST15 is performed as follows. First, the gas supply 20 supplies the first process gas into the plasma processing chamber 10. Then, a plasma generator 12 generates the first plasma PL1 from the first process gas in the plasma processing chamber 10. The controller 2 controls the gas supply 20 and the plasma generator 12 such that the etching target film RE3 is etched with the first plasma PL1. The controller 2 may control the gas supply 20 and the plasma generator 12 such that the etching target film RE3 is etched by promoting a reaction between the etching target film RE3 and the fluorine atom contained in the silylating agent adsorbed to the surface of the etching target film RE3 with the first plasma PL1.

In Step ST15, the reaction between the etching target film RE3 and the fluorine atoms may be promoted by heating the substrate W1 using a heating device instead of the first plasma PL1 or in addition to the first plasma PL1. The heating device may be, for example, one or a plurality of heaters disposed in a ceramic member 1111a of an electrostatic chuck 1111. In addition, the heating device may be, for example, an infrared lamp or the like. The heating temperature may be, for example, 100° C. or higher and 400° C. or lower.

In the method MT2, Step ST14 and Step ST15 may be repeated. At this time, the method MT2 may include Step ST16. In Step ST16, whether or not a stop condition is satisfied is determined. In Step ST16, the stop condition may be satisfied, for example, when the number of times of the repetition reaches a predetermined number of times. Further, in Step ST16, the stop condition may be satisfied, for example, when the depth of the recess RS of the etching target film RE3 has reached a predetermined depth. Further, in Step ST16, the stop condition may be satisfied, for example, when the dimension of the recess RS (for example, the dimension on the bottom surface of the recess RS) of the etching target film RE3 has reached a predetermined dimension. In Step ST16, when it is determined that the stop condition is not satisfied, Steps ST14 and ST15 are performed again. In Step ST16, when it is determined that the stop condition is satisfied, Step ST17 is performed, or the method MT2 is ended.

In Step ST17, the etched substrate W3 is carried out from the plasma processing chamber 10.

In the substrate W3 carried out in Step ST17, as illustrated in FIG. 16, the dimensions of the upper surface (for example, the vicinity of the mask MK) of the recess RS may be substantially equal to the dimensions of the bottom surface (for example, the vicinity of the underlying film UR3) of the recess RS. The substrate W3 carried out in Step ST17 may have the protective film PR, or the protective film PR may be removed.

According to the method MT2 described above, since the silylating agent is adsorbed to the etching target film RE3 in Step ST14, it is possible to efficiently proceed the etching in the adsorption site SR3 where the silylating agent has been adsorbed in Step ST15, and it is possible to control the shape of the recess with high accuracy.

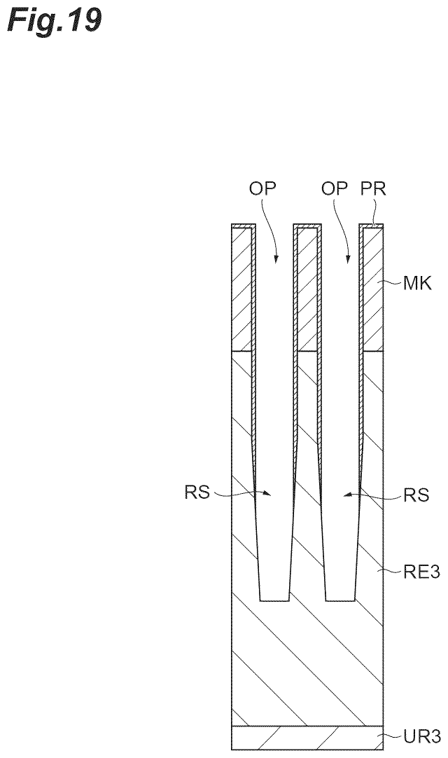

In the method MT2, the bottom of the recess RS does not need to reach the underlying film UR in Step ST12. FIGS. 19 to 21 are diagrams for describing Steps ST13 to ST16 of the method MT2 when the bottom of the recess RS does not reach the underlying film UR in Step ST12.

As illustrated in FIG. 19, when the bottom of the recess RS does not reach the underlying film UR in Step ST12, a protective film PR may be formed at a portion of the side wall of the recess RS in Step ST13. The protective film PR may be formed on the side wall of the opening OP or may be formed on the upper surface of the mask MK.

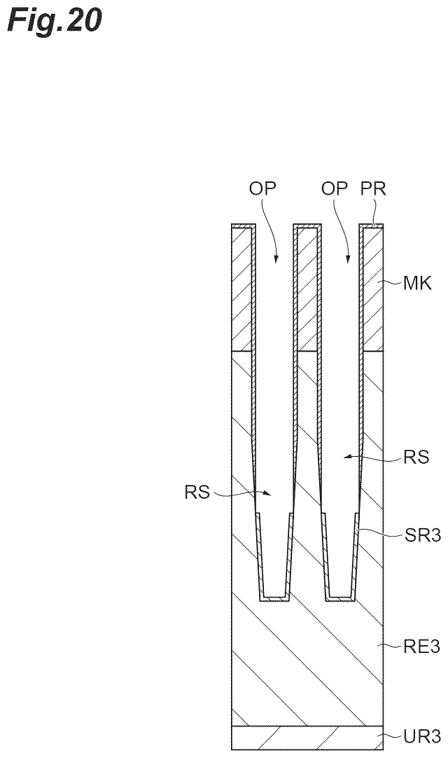

As illustrated in FIG. 20, in Step ST14, the adsorption site SR3 in which the silylating agent is adsorbed may be formed at a portion of the side wall and the bottom surface of the recess RS. Further, in Step ST14, after the silylating agent is adsorbed to the side wall and the bottom surface of the recess RS, the silylating agent on the etching target film RE3 may be removed in the shallow region of the recess RS by a predetermined method, so that the adsorption site SR3 may be selectively formed in the deep region (lower region) of the recess RS. The method of removing the silylating agent in the shallow region is not particularly limited, and removal, for example, with an oxygen radical may be performed. When Step ST14 is a step capable of selectively adsorbing the silylating agent to the deep region (lower region) of the recess RS as described above, Step ST14 may be performed after Step ST12 without performing Step ST13.

In Step ST15, the etching of the etching target film RE3 may selectively proceed at the adsorption site SR3 on the etching target film RE3. Thereby, it is possible to efficiently proceed the etching in a portion where the dimension of the side wall of the recess RS is small and on the bottom surface of the recess RS, and it is possible to control the shape of the recess with high accuracy.

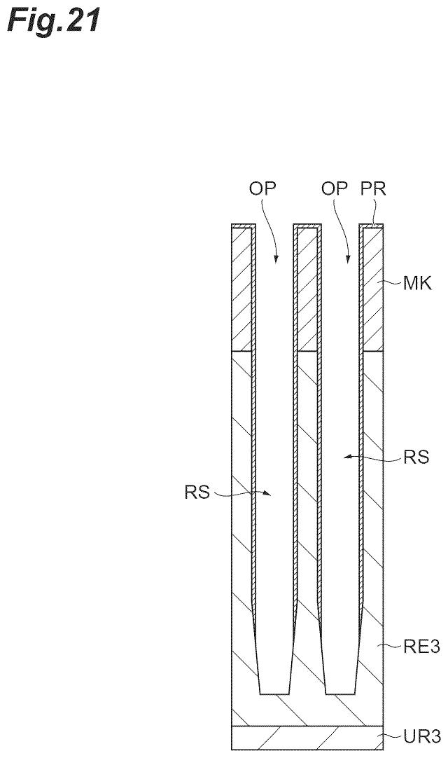

In the method MT2, Steps ST12 to ST15 may be repeated. In the method MT2, Step ST16 may be a step of repeating Steps ST12 to ST15 when it is determined that the stop condition is not satisfied. As illustrated in FIG. 21, the substrate W3 in which a deeper recess RS is formed and a protective film PR corresponding to the shape of the recess RS is formed by Steps ST12 and ST15 again may be provided in Step ST14.

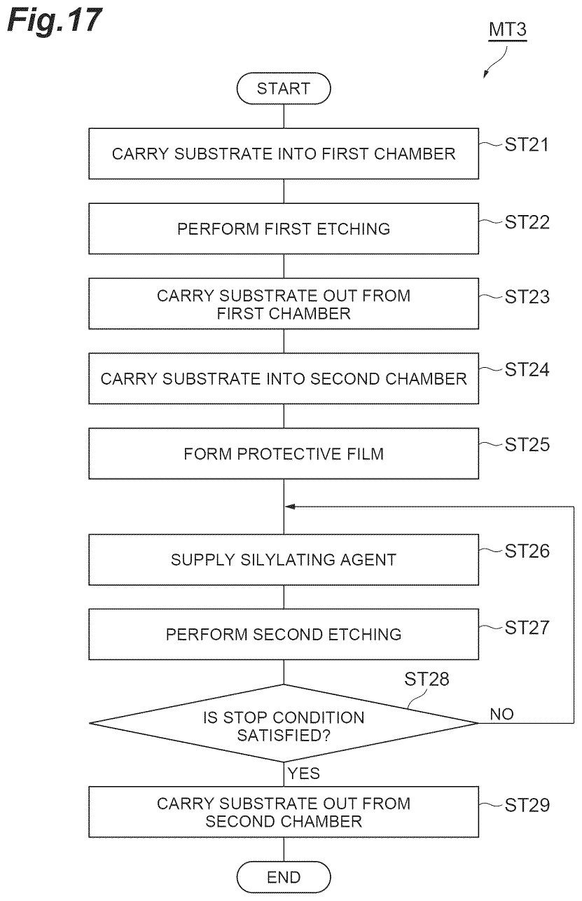

FIG. 17 is a flowchart illustrating an etching method according to an exemplary embodiment. An etching method MT3 (referred to as a “method MT3” below) illustrated in FIG. 17 may be an example of a case where the method MT2 is performed by using a substrate processing system having a plurality of chambers. The method MT3 may be applied to the substrate W3.

In Step ST21, the substrate W3 is carried into a first chamber. Step ST22 corresponds to Step ST12 of the method MT2. Step ST22 may be performed in the similar manner to Step ST12 of the method MT2. In Step ST23, the substrate W3 is carried out from the first chamber.

In Step ST24, the substrate W3 is carried into the second chamber. Steps ST25, ST26, ST27, and ST28 respectively correspond to Step ST13, Step ST14, Step ST15, and Step ST16 of the method MT2. Steps ST25, ST26, ST27, and ST28 may be respectively performed in the similar manner to Steps ST13, ST14, ST15, and ST16 of the method MT2. In Step ST29, the substrate W3 is carried out from the second chamber.

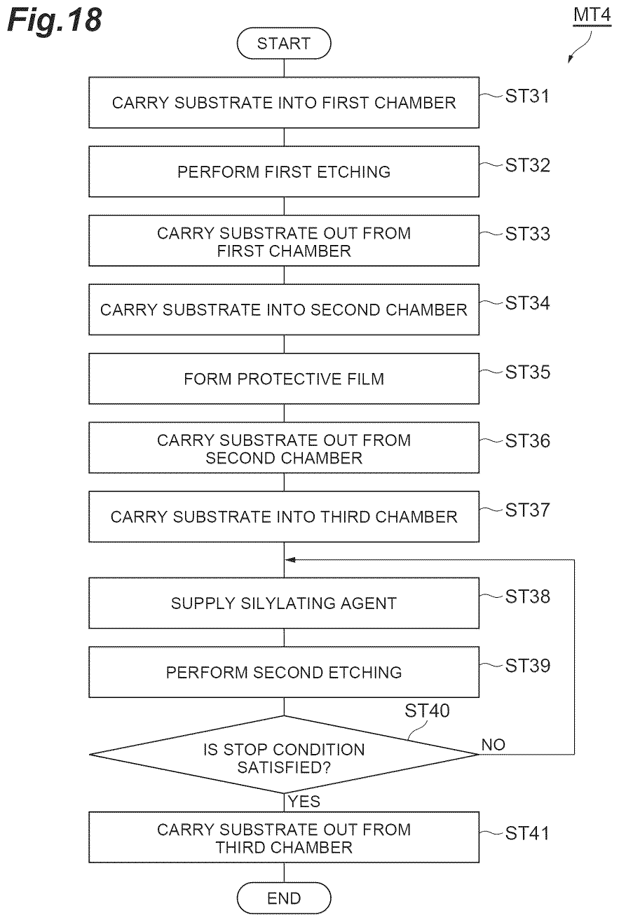

FIG. 18 is a flowchart illustrating an etching method according to an exemplary embodiment. An etching method MT4 (referred to as a “method MT4” below) illustrated in FIG. 18 may be an example of a case where the method MT2 is performed by using a substrate processing system having a plurality of chambers. The method MT4 may be applied to a substrate W3.

In Step ST31, the substrate W3 is carried into the first chamber. Step ST32 corresponds to Step ST12 of the method MT2. Step ST32 may be performed in the similar manner to Step ST12 of the method MT2. In Step ST33, the substrate W3 is carried out from the first chamber.

In Step ST34, the substrate W3 is carried into the second chamber. Step ST35 corresponds to Step ST13 of the method MT2. Step ST35 may be performed in the similar manner to Step ST13 of the method MT2. In Step ST36, the substrate W3 is carried out from the second chamber.

In Step ST37, the substrate W3 is carried into a third chamber. Steps ST38, ST39, and ST40 correspond to Steps ST14, ST15, and ST16 of the method MT2, respectively. Steps ST38, ST39, and ST40 may be performed in the similar manner to Steps ST14, ST15, and ST16 of the method MT2, respectively. In Step ST41, the substrate W3 is carried out from the third chamber.

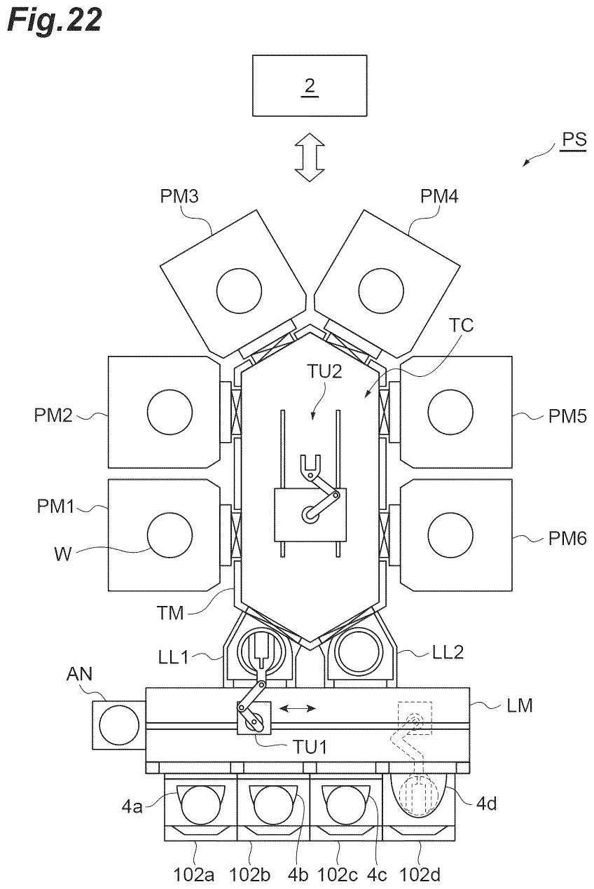

The description will be made below with reference to FIG. 22. FIG. 22 is a diagram illustrating a substrate processing system according to an exemplary embodiment. A substrate processing system PS illustrated in FIG. 22 may be used in the method MT3 or the method MT4. The substrate processing system PS includes load ports 102a to 102d, containers 4a to 4d, a loader module LM, an aligner AN, load lock modules LL1 and LL2, process modules PM1 to PM6, a transport module TM, and the controller 2. The number of load ports, the number of containers, and the number of load lock modules in the substrate processing system PS may be any number of one or more. Further, the number of process modules in the substrate processing system PS may be any number of one or more.

The load ports 102a to 102d are arranged along one edge of the loader module LM. The containers 4a to 4d are respectively mounted on the load ports 102a to 102d. Each of the containers 4a to 4d is, for example, a container called a front opening unified pod (FOUP). Each of the containers 4a to 4d is configured to accommodate the substrate W inside.

The loader module LM has a chamber. The pressure in the chamber of the loader module LM is set to atmospheric pressure. The loader module LM has a transport device TU1. A transport device TU1 is, for example, a transport robot and is controlled by the controller 2. The transport device TU1 is configured to transport the substrate W via the chamber of the loader module LM. The transport device TU1 can transport the substrate W between each of the containers 4a to 4d and the aligner AN, between the aligner AN and each of the load lock modules LL1 and LL2, and between each of the load lock modules LL1 and LL2, and each of the containers 4a to 4d. The aligner AN is connected to the loader module LM. The aligner AN is configured to perform adjustment of the position (correction of the position) of the substrate W.

Each of the load lock module LL1 and the load lock module LL2 is provided between the loader module LM and the transport module TM. Each of the load lock module LL1 and the load lock module LL2 provides a preliminary decompression chamber.

The transport module TM is connected to each of the load lock module LL1 and the load lock module LL2 via a gate valve. The transport module TM has a transport chamber TC in which the internal space thereof is configured to be capable of decompression. The transport module TM has a transport device TU2. The transport device TU2 is, for example, a transport robot and is controlled by the controller 2. The transport device TU2 is configured to transport the substrate W via the transport chamber TC. The transport device TU2 can transport the substrate W between each of the load lock modules LL1 and LL2 and each of the process modules PM1 to PM6, and between any two process modules among the process modules PM1 to PM6.

Each of the process modules PM1 to PM6 is an apparatus configured to perform dedicated substrate processing. One process module among the process modules PM1 to PM6 may be the plasma processing apparatus 1 used in the method MT2.

Steps ST22 of the method MT3 may be performed in one process module among the process modules PM1 to PM6, and Steps ST25 to ST28 of the method MT3 may be performed in another process module among the process modules PM1 to PM6.

Step ST32 of the method MT4 may be performed in one process module among the process modules PM1 to PM6. Step ST35 of the method MT4 may be performed in another process module among the process modules PM1 to PM6. Steps ST38, ST39, and ST40 of the method MT4 may be performed in still another process module among the process modules PM1 to PM6.

Although the various exemplary embodiments have been described above, various additions, omissions, substitutions, and changes may be made without being limited to the exemplary embodiments described above. Other embodiments can be formed by combining elements in different embodiments.

For example, each step of the methods MT1 to MT4 may be freely combined.

In the method MT2, the step of removing the protective film PR may be performed before Step ST17 or after Step ST17. Further, in the method MT2, the step of removing the mask MK may be performed before Step ST17 or after Step ST17.

In the method MT3, the step of removing the protective film PR may be performed before Step ST29 or after Step ST29. Further, in the method MT3, the step of removing the mask MK may be performed before Step ST29 or after Step ST29.

In the method MT4, the step of removing the protective film PR may be performed before Step ST41 or after Step ST41. Further, in the method MT4, the step of removing the mask MK may be performed before Step ST41 or after Step ST41.

From the above description, it will be understood that various embodiments of the present disclosure have been described for purposes of explanation in the present specification, and that various changes may be made without departing from the scope and spirit of the present disclosure. Accordingly, the various embodiments disclosed in the present specification are not intended to limit, and the true scope and spirit are indicated by the appended claims.

What is claimed is:

1. An etching method comprising:
(a) adsorbing a silylating agent having a C—F bond to at least a portion of an etching target film including a silicon-containing film; and
(b) etching the etching target film.

2. The etching method according to claim 1, wherein
in (b), the etching target film is etched by a reaction between the etching target film and a fluorine atom contained in the silylating agent adsorbed to the etching target film.

3. The etching method according to claim 2, wherein
in (b), the reaction is promoted by first plasma generated from a first process gas containing at least one selected from the group consisting of an inert gas and an oxygen-containing gas.

4. The etching method according to claim 2, wherein
in (b), the reaction is promoted by heating the etching target film.

5. The etching method according to claim 1, wherein
the silicon-containing film includes at least one selected from the group consisting of a silicon oxide film and a silicon nitride film.

6. The etching method according to claim 1, wherein
the etching target film includes a silicon oxide film and a film other than the silicon oxide film.

7. An etching method comprising:
(a) providing a substrate including an etching target film that has at least one recess and includes a silicon-containing film; and
(b) adsorbing a silylating agent having a C—F bond to at least a portion of a side wall of the recess; and
(c) etching the etching target film.

8. The etching method according to claim 7, wherein
in (b), the silylating agent is selectively adsorbed to a lower region of the side wall.

9. The etching method according to claim 7, wherein
in (c), the side wall is etched by a reaction between the side wall and a fluorine atom contained in the silylating agent adsorbed to the side wall.

10. The etching method according to claim 9, wherein
in (c), the reaction is promoted by first plasma generated from a first process gas containing at least one selected from the group consisting of an inert gas and an oxygen-containing gas.

11. The etching method according to claim 7, wherein
in (c), a lower region of the side wall is etched in a horizontal direction.

12. The etching method according to claim 7, further comprising:
forming a protective film on at least a portion of the side wall after (a) and before (b).

13. The etching method according to claim 12, further comprising:
forming a protective film in an upper region of the side wall after (a) and before (b),
wherein, in (c), a lower region of the side wall is etched in a horizontal direction.

14. The etching method according to claim 12, wherein
the protective film is formed by a method selected from the group consisting of an ALD method, a CVD method, and an MLD method.

15. The etching method according to claim 12, wherein
the protective film has a first thickness on a first region of the side wall of the recess, and has a second thickness smaller than the first thickness on a second region at a position deeper than the first region of the side wall of the recess.

16. The etching method according to claim 7, wherein
(a) includes
(a-1) providing a substrate including the etching target film and a mask on the etching target film, in which the mask has at least one opening, and
(a-2) forming the recess by etching the etching target film via the opening with second plasma generated from a second process gas.

17. The etching method according to claim 7, wherein
an aspect ratio of the recess is 5 or more.

18. The etching method according to claim 7, wherein
(b) includes
(b-1) adsorbing the silylating agent to at least the portion of the side wall of the recess, and
(b-2) removing a portion of the silylating agent adsorbed to the side wall after (b-1).

19. A plasma processing apparatus comprising:
a chamber;
a substrate supporter that supports a substrate in the chamber, the substrate having an etching target film including a silicon-containing film; and
a gas supply configured to supply a silylating agent having a C—F bond into the chamber.

20. The plasma processing apparatus according to claim 19, further comprising:
a controller,
wherein the controller is configured to perform processing of etching the etching target film by a reaction between the etching target film and a fluorine atom contained in the silylating agent adsorbed to the etching target film, after the silylating agent is adsorbed to at least a portion of the etching target film.
